(19) United States
(12) Patent Application Publication
(10) Pub. No.: US 2019/0319580 A1
(43) Pub. Date: Oct. 17, 2019

(54) Photo voltaic device

(71) Applicant: Robert Phares Dildine, New Knoxville, OH (US)

(72) Inventor: Robert Phares Dildine, New Knoxville, OH (US)

(21) Appl. No.: 16/501,425

(22) Filed: Apr. 15, 2019

Related U.S. Application Data
(60) Provisional application No. 62/762,003, filed on Apr. 16, 2018.

(51) Int. Cl. H02S 40/22; H02S 30/10; H01L 31/0445; H02S 20/32

(52) U.S. Cl. CPC H02S 40/22; H02S 20/32; H01L 31/0445; H02S 30/10

(57) ABSTRACT

A solar panel comprises a cell mounting surface and a cell array having a photon absorbent surface. Moreover, the cell array is coupled to the cell mounting surface such that the photon absorbent surface of the cell array is at an angular position different than the cell mounting surface. Furthermore, the cell array is a part of a system comprising a solar panel, a foundational base, and a tracking system. The system is enclosed within the foundational based and further coupled to a tracking system. The tracking system controls an angle of the panel and re-orients the position of the photon absorbent surface of the cell array to a position of the sun.

### CROSS-REFERENCE TO RELATED APPLICATIONS

This application claims the benefit of U.S. Provisional application 62/762,003, Titled Optimal Photo Voltaic Panels and Arrays, filed on Apr. 16, 2018, the disclosure by which is incorporated in its entirety.

### BACKGROUND

### Field of the Invention

Various aspects of the present invention relate generally to solar panel assembly and specifically to geometrical arrangement of photovoltaic cells within a given solar panel.

### Description of the Related Art

Solar energy is the radiant energy captured from the sun and converted into thermal or electrical energy for residential and commercial uses. Commonly, solar panels are either fixed panels or utilize tracking systems to periodically align the panel with the sun. Fixed solar panels typically generate low levels of output efficiency throughout a given day. Tracking systems can be utilized to increase this output efficiency of the solar panel by periodically aligning the solar panel with the sun.

### BRIEF SUMMARY

According to aspects of the present disclosure, systems and methods are provided for a significant increase in wattage per square foot area of a solar panel. For some embodiments, the system comprises a series of cell arrays, adjoined together within a footprint of the panel and arranged at an angular position different than the surface of the solar panel.

According to further aspects of the present invention, a solar panel comprises a cell mounting surface and a cell array having a photon absorbent surface. Moreover, the cell array is coupled to the cell mounting surface such that the photon absorbent surface of the cell array is at an angular position different than the cell mounting surface.

According to still further aspects of present invention, a solar panel comprises a cell mounting surface, a first cell with a photon absorbent surface and a reflective surface opposite the photon absorbent surface, and a second cell array with a photon absorbent surface. Both the first cell array and the second cell array are coupled to the cell mounting surface such that the photon absorbent surface of the first cell array and the second cell array are at an angular position different than the cell mounting surface.

According to even further aspects of the present invention, a system comprises a panel having a reflective cell mounting surface, a first cell with a photon absorbent surface and a reflective surface opposite the photon absorbent surface, a second cell array with a photon absorbent surface, a foundational base, and a tracking system. Both the first cell array and the second cell array are coupled to the cell mounting surface such that the photon absorbent surface of the first cell array and the second cell array are at an angular position different than the cell mounting surface. The foundational base is coupled to the bottom of the panel and the tracking system. The tracking system controls an angle of the panel relative to the foundational base that re-orients the position of the photon absorbent surface of the first cell array and the photon absorbent surface of the second cell array relative to a position of the sun.

### BRIEF DESCRIPTION OF THE SEVERAL VIEWS OF THE DRAWINGS

FIG. 1 is a top down view of an example solar panel cell mounting surface;

FIG. 2. is a side view of an example cell array coupled to the cell mounting surface comprising a photon absorbent surface opposite a reflective surface;

FIG. 3 is a top down view of an example of the photon absorbent surface of a cell array;

FIG. 4 is a side view of an example of a cell array coupled to the cell mounting surface and held at a relative angular position different than the cell mounting surface;

FIG. 5A is a front view of an example of the frame;

FIG. 5B is a side view of an example of the frame comprising an attachment;

FIG. 6 is a side view of an example of a cell array coupled to the cell mounting surface and further held at an angular position different than the cell mounting surface by a support;

FIG. 7 is a top down view of an example footprint within the cell mounting surface comprising a set of cell arrays within the footprint;

FIG. 8 is a side view of an example first cell array and a second cell array held at a relative angular position different than the cell mounting surface;

FIG. 9 is a side view of an example of a set of cell arrays held at a relative angular position different than the cell mounting surface;

FIG. 10 is a close up view of an example of the light particle behavior between the photon absorbent surface of the first cell array and the photon absorbent surface of the second cell array;

FIG. 11 is a front view of an example of a set of cell arrays electrically coupled to one another and adjoined side by side on the cell support surface;

FIG. 12 is a cross-section view of an example of the solar panel system; and

FIG. 13 is a perspective view of an example of the solar panel system.

### LEXICON

As used herein, “cell” is a schematic representation of a cell array.

As used herein, “cell array” means one or more photovoltaic cells that are semiconductor devices that can convert solar energy into electricity.

As used herein, “module” means an assembly of closely packed cell arrays.

As used herein, “panel” means a connected series of cell arrays.

As used herein, “non-coplanar cell” means a cell array which is at a different angular position than its substrate.

As used herein, “photon absorbent surface” means a surface which absorbs photons and sunlight.

As used herein, “reflective surface” means a surface which does not absorb photons or sunlight.

As used herein, “footprint” means the surface of the cell mounting surface which a cell occupies on the solar panel surface.

As used herein, “angle of incidence” means the angle a ray of sunlight creates with a line perpendicular to a surface.

As used herein, “angle of reflection” means the angle created by a reflected ray of sunlight with a surface perpendicular to the reflecting surface.

As used herein, “zenith angle” means the angle between the sun and the vertical, the zenith angle is essentially the position of the sun in the sky.

As used herein, “orthogonal surface” is any surface that is normal.

As used herein, “normal” means perpendicular to a level surface.

### DETAILED DESCRIPTION

The energy output of a photovoltaic solar panel changes based on the angle between the panel and the sun. The location of the sun throughout a given day directly correlates to a solar panels efficiency due to the specific angle the sunlight hits the panel, the angle of incidence. The angle of incidence is instrumental in choosing both a location and position of the solar panel. Solar panels comprise photovoltaic cell arrays that can produce electricity from a range of frequencies of light, but usually cannot cover the entire solar range throughout the day if the solar panel is in fixed position. Thus, many fixed solar panels use a solar tracking system to optimize the amount of sunlight that hits a photovoltaic solar panel. Even with use of a tracking system, these solar panels do not steward power available per footprint area of a given solar panel.

However, according to aspects of the present disclosure, a means for increasing the efficiency of photovoltaic cell arrays on a solar panel is provided. Cell efficiency is the power output of a photovoltaic cell and by using geometrical shaping and organization of the cell arrays on a solar panel, the disclosed invention increases solar panel efficiency. Increased efficiency is achieved by angling the cells on a solar panel in order to fit more cells within a footprint of the surface of the panel. Generally, solar panels comprise photovoltaic cells arranged such that the face of the photovoltaic cell array is co-planar with the solar panel surface. When the sun is directly above the solar panel, this arrangement provides an angle of incidence of zero degrees and increases the angle of reflection without an opportunity to recapture the sunlight. Therefore, the efficiency of a solar panel is capped at a maximum efficiency depending on the position of the solar panel. The addition of tracking systems does not provide the opportunity to recapture the reflected sunlight if the cells are co-planar with the solar panel surface. Arranging a set of cells at an angular position different than the solar panel surface such that the angle of incidence and reflective angles are reduced provides an opportunity for sunlight recapture is achieved.

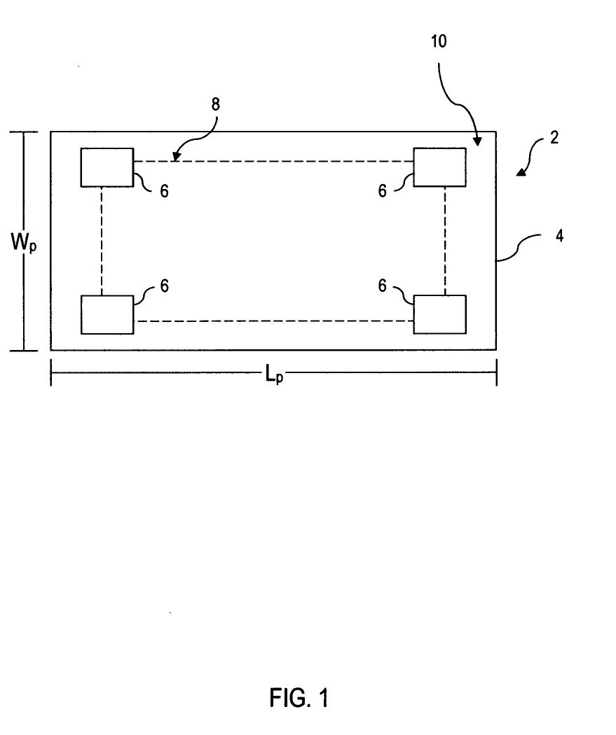

Referring now to the drawings and in particular FIG. 1, a solar panel 2 with a cell mounting surface 4 comprising a cell 6 is shown. The cell 6 is a schematic representation of a cell array 6 and a set of cell arrays 6. The cell array 6 occupies a footprint 8 on the cell mounting surface 4. The footprint is defined as an area the cell array 6 would occupy if the cell array 6 were co-planar with cell mounting surface 4. In the illustrated embodiment, the footprint 8 is equal to a length and width area as if the cell array 6 were co-planar with the cell mounting surface 4. The cell mounting surface 4 comprises a reflective surface. When sunlight comes into contact with the solar panel 2, some of the sunlight is absorbed while some of the sunlight is reflected. A present objective of the current invention is to provide an opportunity for reflected sunlight to be recaptured by the cell array 6. A reflective surface on the cell mounting surface 4 increases the opportuning to recapture reflected sunlight by the cell array 6 by directing light impinging the cell mounting surface 4 to the cell array 6.

In a first illustrative example, implementation, the reflective cell mounting surface 4 comprises aluminum or photon non-absorbent media. Aluminum or photon non-absorbent media has advantageous reflective properties, it is lightweight, and easily processed and low cost. Use of aluminum or photon non-absorbent media as the reflective surface affords significant advantages in reducing manufacturing costs and does not jeopardize efficiency of the solar panel 2. Aluminum or photon non-absorbent media further provides a mirror substrate to couple the cell array 6. Coupling the cell array 6 to an aluminum or photon non-absorbent media cell support surface 4 provides a significant increase in sunlight absorption by providing an opportunity for sunlight impinging the aluminum or photon non-absorbent media cell mounting surface 4 to be directed toward the cell array 6. In an alternative embodiment, the reflective surface of the cell mounting surface 4 comprises aluminum or photon non-absorbent media as a thin film coating material on a rigid substrate. Aluminum or photon non-absorbent media can be vacuum deposited onto glass, metals, ceramics, or a combination thereof, as a thin film coating. When aluminum or photon non-absorbent media is vacuum deposited onto such substrates, it generates a metal or glass mirror. This mirror can have the mechanical and thermal properties of the substrate but will also exhibit the optical properties of aluminum. This concept provides a significant advantage in the manufacturing process of the solar panel. Cheaper resources may be used as the cell mounting surface 4 and further comprise aluminum vacuum deposited as a thin film coating. The composition of the cell mounting surface 4 may be conditional upon the type of photovoltaic cell used in the solar panel 2. Discussed in more detail later, all photovoltaic cells comprise silicon because silicon determines the cells photovoltaic effect. However, photovoltaic cells may be manufactured in monocrystalline, polycrystalline, amorphous silicon, or any combination thereof. Absorption and manufacturing cost will depend on the type of photovoltaic cell used in the solar panel 2. However, regardless of the type of cell, the angle of reflection changes along with the position of the sun.

In a second illustrative example, the solar panel 2 and cell mounting surface 4 is a rigid reflective surface. Typically, solar panels comprise rigid surfaces and are oriented in a fixed position. For instance, the cell mounting surface of conventional solar panels is a solid substrate comprising cells arranged co-planar with the solar panel surface. In the illustrated embodiment, the solar panel 2 and cell mounting surface 4 comprise rigid surfaces in order to support the cell array 6 arranged at an angular position different than the cell mounting surface 4. Angling the cell array 6 requires that the cell array 6 be supported at a relative angle in order to maintain its efficiency. A rigid cell mounting surface 4 provides a means to maintain the fixed angular position of the cell array 6 over a period of time.

In alternative embodiments, the solar panel 2 and cell mounting surface 4 comprise a flexible cell mounting surface 4. For example, the flexible cell mounting surface 4 comprises amorphous silicon photovoltaic cells applied to a thin, flexible substrate such as glass, metal, plastic, or any combination thereof. A solar panel 2 with a flexible cell mounting surface 4 will decrease the overall weight of the solar panel 2 while maintaining the electrical and thermal properties required for radiant solar energy absorption. This concept provides a significant increase in applications of the solar panel 2. Residential use of solar panels is dependent upon the residential capabilities, such as the weight a given roof can support without structural damage. A flexible cell mounting surface 4 decreases the overall weight of the solar panel 2 which increases the application to different types of residential property. For example, a solar panel 2 with a flexible cell mounting surface 4 can be applied to residential homes and commercial buildings with roofs that cannot support the weight of traditional solar panels, recreational vehicles; water vehicles such as house boats, off-grid applications, or any combination thereof.

Furthermore, use of a flexible cell mounting surface 4 on any of these applications enables the solar panel to adhere to the contour of its substrate. Following the contour of the substrate is attractive for aesthetic purposes, as well as, increases efficiency by prolonging the solar panel's 2 exposure to sunlight. For example, a flexible solar panel 2 and a cell mounting surface 4 can properly adhere to the curved roof of a home or vehicle. As the sun rotates along its axis throughout the day, a typical fixed solar panel can only absorb sunlight while the cells are exposed to the sun. Even then, the sunlight is reflected off the surface of the cell array 6 without opportunity to be recaptured. The combination of the flexible solar panel 2 and cell mounting surface 4 following the contour of the substrate surface and the cell arrays 6 at an angular position different than the cell mounting surface 4 provides a unique advantage for the solar panel 2. This combination increases the opportunity of a sunlight recapture and, thus, increases the solar panel 2 efficiency.

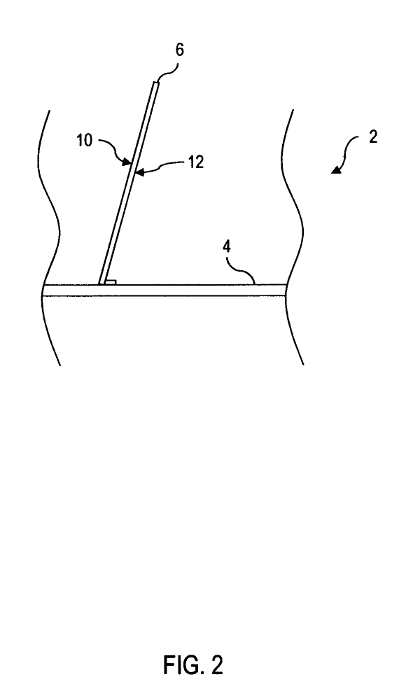

Referring to FIG. 2, a solar panel 2 comprising a cell mounting surface 4 and a cell array 6 is schematically shown. The cell array 6 comprises a photon absorbent surface 10 and a reflective surface 12 opposite the photon absorbent surface 10. The cell array 6 is arranged at an angular position different than the cell mounting surface 4 in order to increase the efficiency of the solar panel 2. Angling the cell array 6 at a different angular position than the cell mounting surface 4 provides two significant advantages, the second to be discussed at a later time. In a first illustrative example, implementation, the angular position of the cell array 6 is different than the cell mounting surface 4, allowing additional cell arrays 6 to occupy the same footprint 8 as if a single cell array 6 were co-planar with the cell mounting surface 4. For instance, arranging the cell arrays 6 at a different angular position allows for at least two cell arrays 6 to occupy the same footprint 8 on the cell mounting surface 4. In alternative embodiments, the cell array 6 is a plurality of cell arrays 6 with each cell array 6 comprising a photon absorbent surface 10 and a reflective surface 12 opposite the photon absorbent surface 10.

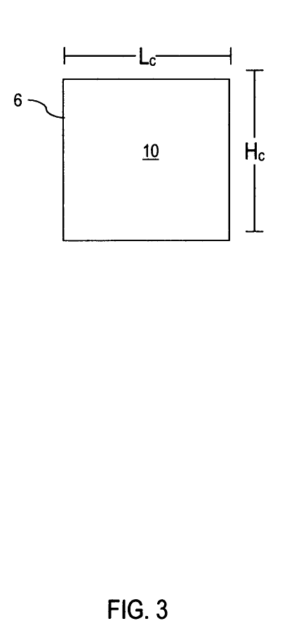

Referring now to FIG. 3, a photon absorbent surface 10 of a cell array 6 is depicted. In the illustrated embodiment, the photon absorbent surface 8 is equal to a length and height of the cell array 6. For example, the photon absorbent surface 10 covers an entire surface of the cell array 6. Having a photon absorbent surface 10 cover an entire surface of the cell array 6 increases sunlight absorption. The height and length of the cell array 6 is conditional upon the type of photovoltaic cell. For example, photovoltaic cells may be manufactured in monocrystalline, polycrystalline, amorphous silicon, or any combination thereof. In the illustrated embodiment, the cell array 6 is a monocrystalline photovoltaic cell produced from one large silicon block and manufactured into a silicon wafer format. The height and length of the cell array 6 is conditional upon the size of the wafer from the manufacturing process. In alternative embodiments, the cell array 6 is a crystalline silicon photovoltaic cell, a polycrystalline photovoltaic cell, an amorphous silicon cell, or any combination thereof. Regardless of the type of photovoltaic cell used in the solar panel 2, each cell array 6 comprises a photon absorbent surface 10 that absorbs sunlight and converts the sunlight into electricity.

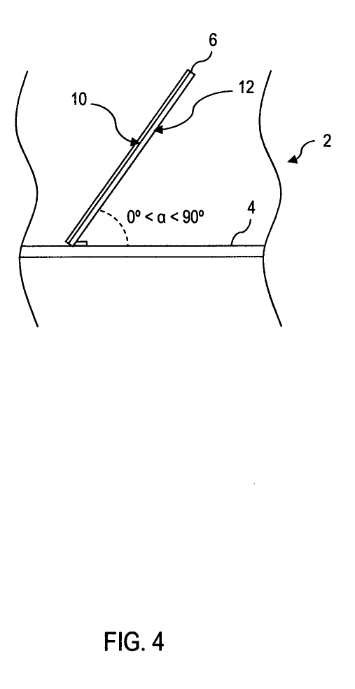

Referring now to FIG. 4, a cell array 6 arranged at a different angular position than the cell mounting surface 4 is depicted. A previously discussed, a first advantage of arranging the cell array 6 at an angular position different than the cell mounting surface 4 is to maximize the amount of cell arrays 6 which may occupy a given footprint 8. For example, Arranging the cell arrays 6 at an angular position different than the cell mounting surface 4 allows roughly three and a half rows of cell arrays 6 to occupy the same footprint 8 as if a cell array was co-planar with the cell mounting surface 4. In order to maintain at least seventy percent efficiency with 20 percent efficient cells of the cell array 6, the cell array 6 is arranged an angular position greater than zero degrees and less than eighty-five degrees of a planar, cell support surface.

In the illustrated embodiment, the cell array 6 is arranged at an angular position of seventy-five degrees to a planar surface of the cell mounting surface 4 and fifteen degrees from normal to the sun. At this angle, cell array 6 output decreases as it approaches parallel to the sun but when arranged at seventy-five degrees the cell array 6 output at fifteen degrees normal to the sun has its output reduced to seventy percent of full output. However, at this different angular position, over three rows of cell arrays 6 can be fit into the same area which offsets any lost output by an individual cell array 6. In alternative embodiments, the photon absorbent surface 10 of the cell array 6 is arranged at an angle greater than five degrees and less than twenty degrees from normal of to the sun. In still further alternative embodiments, the cell array 6 is arranged at an angular position greater than five degrees but less than eighty-five degrees to a planar surface of the cell mounting surface 4.

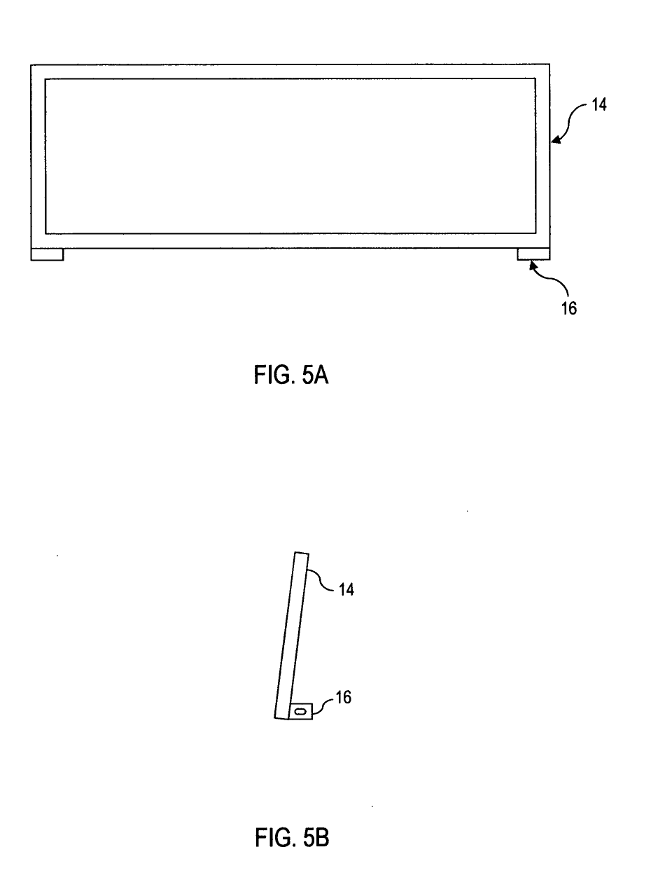

Referring now to FIG. 5A and FIG. 5B, a support 14 is depicted. The support is a schematic representation of a frame 14. In the illustrated embodiment, the frame 14 is a rigid support structure that fixedly orients the entire photon absorbent surface 10 of the cell array 6 at the angular position different than the cell mounting surface 4. In the illustrated embodiment of FIG. 5A, the frame is substantially rectangular in order to accommodate for the shape of the photovoltaic cell array 6. In alternative embodiments, the frame is not substantially rectangular. Rather the frame 14 has a shape corresponding to the shape and type of photovoltaic cell used in the solar panel 2.

In further alternative embodiments, the frame 14 is a solid enclosure comprising a hollowed center. The frame receives the cell array 6 and the hollow center provides a window for the photon absorbent surface 10 of the cell array 6 to be exposed to the sun. In this solar panel 2, any type of photovoltaic cells may be used and fixedly coupled to the cell mounting surface 4. In the illustrated embodiment, the frame 14 comprises aluminum in order to maximize the opportunity to recapture reflected sunlight. As previously discussed, aluminum has reflective properties and an aluminum frame further increases the sunlight recapturing opportunity. In even further alternative embodiments, the frame 14 is a flexible structure comprising flexible encapsulation material. A flexible frame 14 provides a greater resistance to weather and degrading agents such as thermal shock, fog, high winds, solar radiation, or any combination thereof. A flexible structure also provides a greater ability to adjust to the contour of the substrate that the frame 14 is coupled to.

In the illustrated embodiment of FIG. 5B, the frame 14 comprises an attachment 16 that couples the frame 14 to the cell mounting surface 4. The attachment 16 comprises a hole allowing the attachment 16 to couple the frame 14 to the cell mounting surface 4 by a fixing; such as, screws, nails, bolts, or any combination thereof. The cell array 6 is coupled to the frame 14 and fixedly held at a relative angle to the cell mounting surface 4. The cell array 6 is coupled to the frame 14 via adhesive material. For example, ethylene vinyl acetate is a common adhesive material used to couple the cell array 6 to the frame 14. In alternative embodiments, the attachment 16 is a solid extension of the frame 14 and couples the frame 14 to cell mounting surface 4 by an adhesive material.

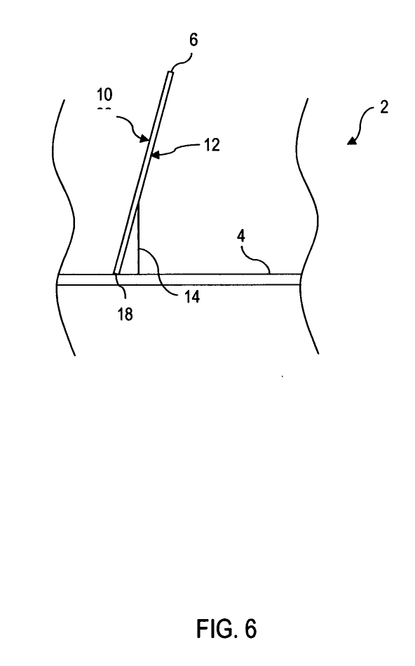

Referring now to FIG. 6, a cell array 6 held at an angular position by a support 14 is depicted. In the illustrated embodiment, the cell mounting surface 4 comprises a channel 18 which receives an edge of the cell array 6. The edge is any edge of the cell array 6 as long as the photon absorbent surface 10 of the cell array 6 is at an angular position different than the cell mounting surface 4. The cell array 6 is further coupled to the cell mounting surface 4 along its associated mounting edge and held at a relative angle by the support 14. In an alternative embodiment, the cell mounting surface 4 does not comprise a channel and the cell array 6 is fixedly coupled to the cell mounting surface via the support 14. In the illustrated embodiment, the support 14 is an aluminum support coupled to the reflective surface 12 of the cell array 6. The support 14 is not fixedly coupled in order to reposition the cell array 6 at a different angular position in order to keep the cell array 6 in a direction of the sun. In an alternative embodiment, the support 14 is fixedly coupled to the cell mounting surface 4.

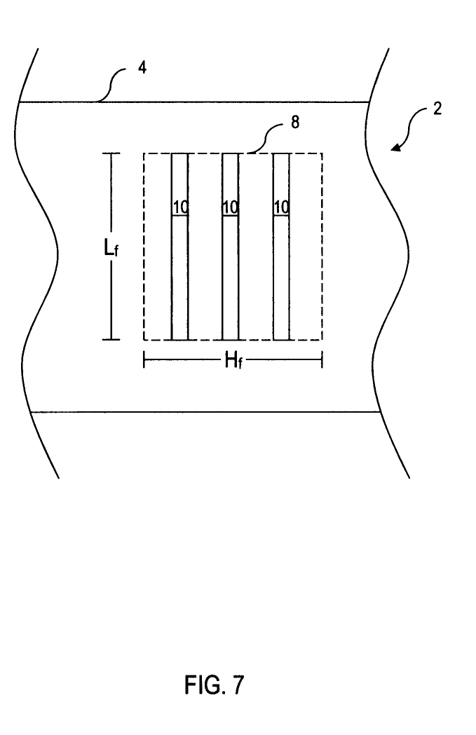

Referring now to FIG. 7, a set of cell arrays 6 occupying a footprint 8 on the cell mounting surface 4 of the solar panel 2 is depicted. As previously discussed, arranging the set of cell arrays 6 at an angular position different than the cell mounting surface 4 allows more cell arrays 6 to occupy the same footprint 8 as if a single cell array were co-planar with the cell mounting surface 4. In the illustrated embodiment, the footprint is defined as an area equal to a length and height area that one cell array 6 occupies when arranged at zero degrees. Angling the cell arrays 6 provides more surface area that other cell arrays 6 may occupy without decreasing the overall surface area of the solar panel 2. When arranged in such a manner, each cell array 6 occupying the footprint 8 comprises an efficiency greater than a single cell array 6 arranged co-planar with the cell mounting surface 4. In a first illustrative example, implementation, arranging the cell arrays 6 at a different angular position provides three times the occupancy than a single cell array 6 would occupy if arranged at zero degrees within the footprint 8.

Increasing the amount of cell arrays 6 that can occupy a single footprint 8 increases the efficiency of the solar panel 2 by changing an output variation of the solar panel 2. Typically, solar panels are confined to an efficiency which equals the efficiency and number of photovoltaic cells within the panel. Therefore, the set of cell arrays 6 increases the amount of sunlight captured for a solar panel 2 which increases the solar panel 2 efficiency.

Arranging the set of cell arrays 6 arranged at a different angular position decreases individual cell array 6 output while increasing capacity of cell arrays 6 within the footprint 8. This increased capacity offsets the decreased output of each individual cell array. The efficiency of the set of cell arrays 6 in combination is greater than the efficiency of an individual cell array 6. For example, the efficiency of the cell array 6 at a specified degree is equal to the efficiency of a cell array 6 arranged at zero degrees divided by more than one cell array 6. The set of cell arrays 6 has a varying output per orientation to the sun but this output of the set of cell arrays 6 is equivalent or exceeds efficiency of a single cell array if arranged co-planar with the cell mounting surface 4. Therefore, a set of cell arrays 6 generates a higher output per each footprint 8 of the solar panel 2 than conventional solar panels.

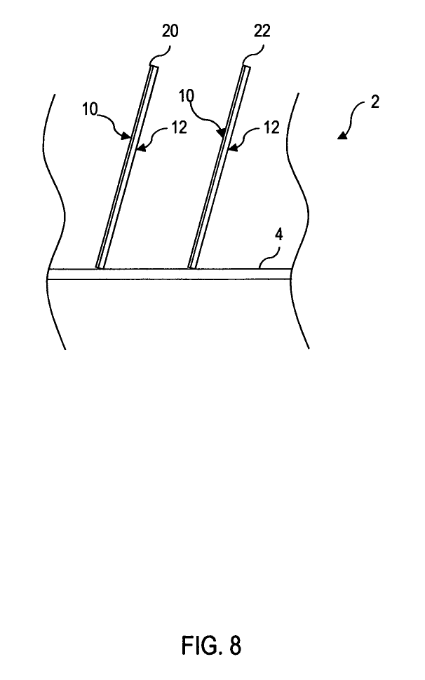

Referring now to FIG. 8, a set of cell arrays 6 arranged at an angular position different than the cell mounting surface 4 is depicted. The cell array 6 is a schematic representation of a first cell array 20 and a second cell array 22. The first cell array 20 and the second cell array 22 each comprise a photon absorbent surface 10 opposite a reflective surface 12. The first cell array 20 is arranged such that the reflective surface 12 of the first cell array 20 is facing and in front of the photon absorbent surface 10 of the second cell array 22 such that light impinging the reflective surface 12 of the first cell array 20 is reflected toward the photon absorbent surface of the second cell array 22. The second major advantage of the solar panel 2 is to utilize the angular position of the first cell array 20 and second cell array 22 to maximize the opportunity to recapture the sun's rays that reflect of each associated cell array 20, 22. In the illustrated embodiment, the reflective surface of the cell mounting surface 4 is positioned such that it reflects light to the photon absorbent surface 10 of the first cell array 20, the photon absorbent surface 10 of the second cell array 22, the reflective surface 12 of the first cell array 20, the reflective surface 12 of the second cell array 22, or a combination thereof. As explained in more detail herein, under the principle of angle incidence, this arrangement provides a consistently higher output per footprint area of the solar panel 2.

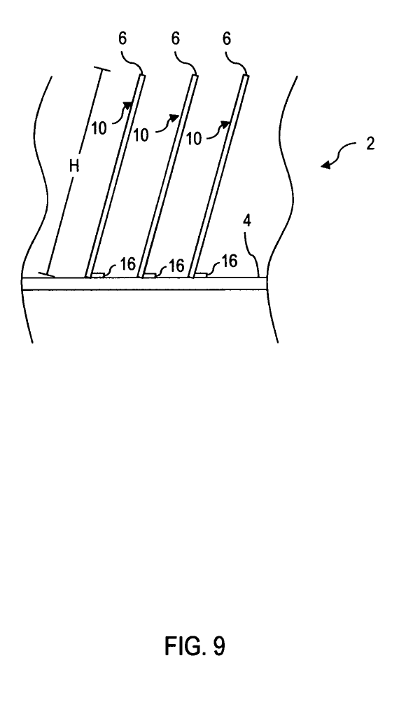

Referring now to FIG. 9, a set of cell arrays 6 coupled to the cell mounting surface 4 is depicted. The set of cell arrays 6 is schematic representation of a plurality of cell arrays 6 arranged in the manner described in paragraph 53.

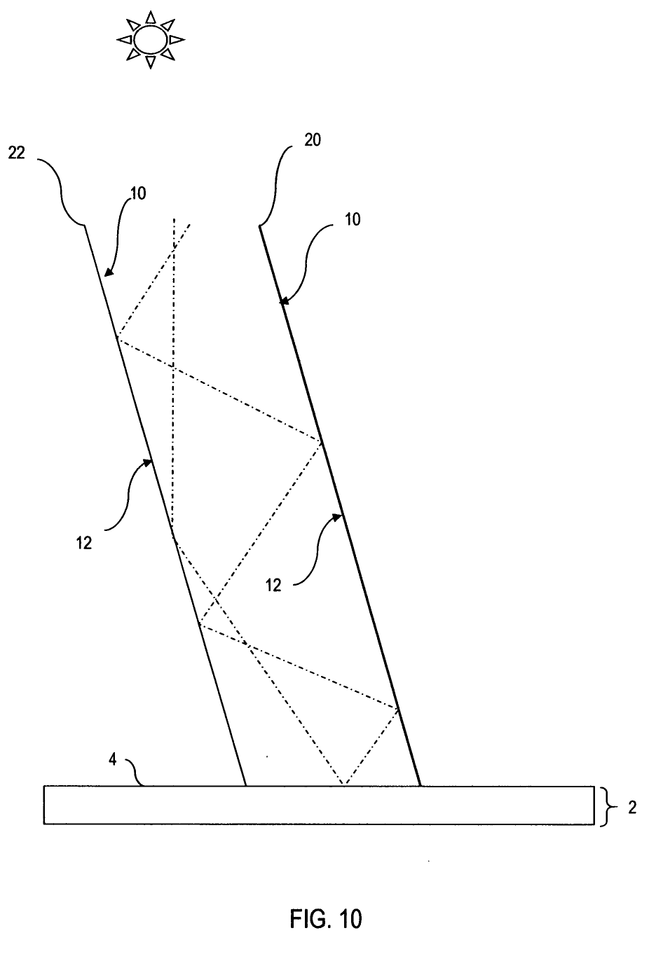

Referring now to FIG. 10, light particle behavior in relation to the angled first cell array 20 and the second cell array 22 is depicted. When sunlight impinges on a solar panel 2, the sun's rays are either absorbed or reflected. The angle of reflection depends on the angle that the sunlight comes into contact with a surface which creates the angle of incidence. The angle of incidence on a solar panel is the angle the sun's rays creates with a line perpendicular to a surface. By way of example, a solar panel directly facing the sun will be orthogonal with the sun and has an angle of incidence of zero. A solar panel parallel to the sun is non-orthogonal to the sun and has an angle of incidence of ninety degrees. Solar panels with an incidence angle of ninety degrees more readily absorb the sun's rays while solar panels at lower angles tend to reflect the sunlight. In a first illustrative example, the photon absorbent surface 10 of the first cell array 20 is at a different angular position than the cell mounting surface 4 and is non-orthogonal to the sun. The different angular position of the first cell array 20 has an angle of incidence of more than ninety degrees.(?) The second cell array 22 is arranged behind and facing the reflective surface 12 of the first cell array 20 and the second cell array has an angle of incidence equal to the first cell array 20.

By positioning the first cell array 20 at a position in front of the second cell array 22, any unabsorbed light impinging the photon absorbent surface 10 of the second cell array 22 is either absorbed or reflected toward the reflective surface of the cell mounting surface 4, the reflective surface 12 of the first cell array 20, or any combination thereof. The first cell array 20 and the second cell array 22 at the different angular positions decreases the angle of incidence as the sun comes into contact with the photon absorbent surface 10 of the second cell array 22 at fifteen degrees from normal. Decreasing the angle of incident reduces the intensity of light on the photon absorbing surface 10 of the second cell array 22 and increases the reflection of sunlight the photon absorbing surface 10 of the second cell array 22. The first cell array 20 and the second cell array 22 are arranged at an angle less than ninety degrees and, thus, increases the reflection of the photon absorbent surfaces 10 of the first cell array 20 and the second cell array 22.

While the different angular position of the first cell array 20 and second cell array 22 increases reflection of sunlight, the first cell array 20 and the second cell array 22 are arranged such that light is directed toward the photon absorbent surface 10 of the second cell array 22. Increasing the number of cell arrays 20, 22 on the solar panel 2 further increases the overall efficiency of the solar panel 2.

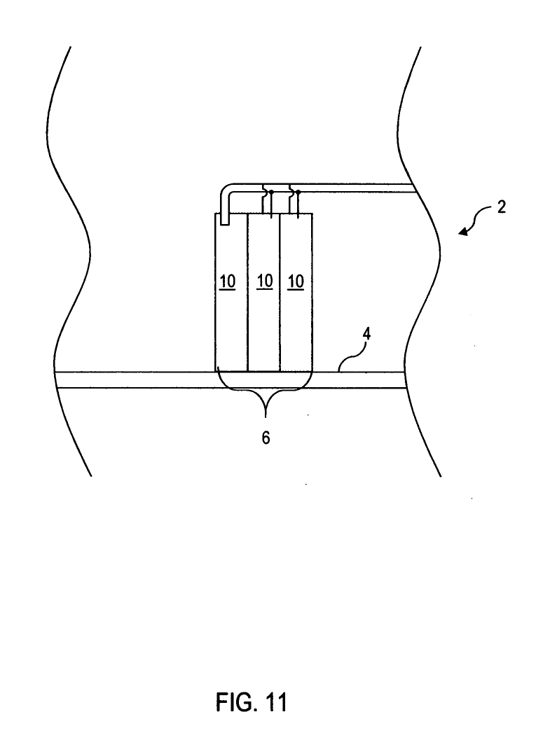

Referring now to FIG. 11, a cell array 6 comprising a set of cells 6 electrically coupled and adjoined side by side is depicted. In the illustrated embodiment, the set of cells 6 are electrically connected and adjoined side by side at a length direction of the cell mounting surface 4. In an alternative embodiment, the set of cells 6 are adjoined at a width direction of the cell mounting surface 4. In the illustrated embodiment, the set of cell arrays 6 are arranged such that the cell arrays 6 are touching and the photon absorbent surfaces 10 of each cell array 6 are facing the same direction such that the photon absorbent surfaces 10 are at a different angular position than the cell mounting surface 4. The photon absorbent surface 10 of the cell arrays 6 is facing the sun and arranged at a relative angle in order to maximize sunlight absorption by the photon absorbent surface 10 of the associated cell array 6. Arranging the cell arrays 6 in this manner also increases the particle behavior in relation to the first cell array 20 and the second cell array 22 as previously described in paragraphs 55-57. In an alternative embodiment, the set of cell arrays 6 are adjoined side by side and arranged with a gap between the cell arrays 6. Leaving ample room for sunlight to move between the set of cell arrays 6 increases the absorption of the second cell array 6 as sunlight is able to penetrate this space and be directly absorbed by the photon absorbent surface 10 of the second cell array 22.

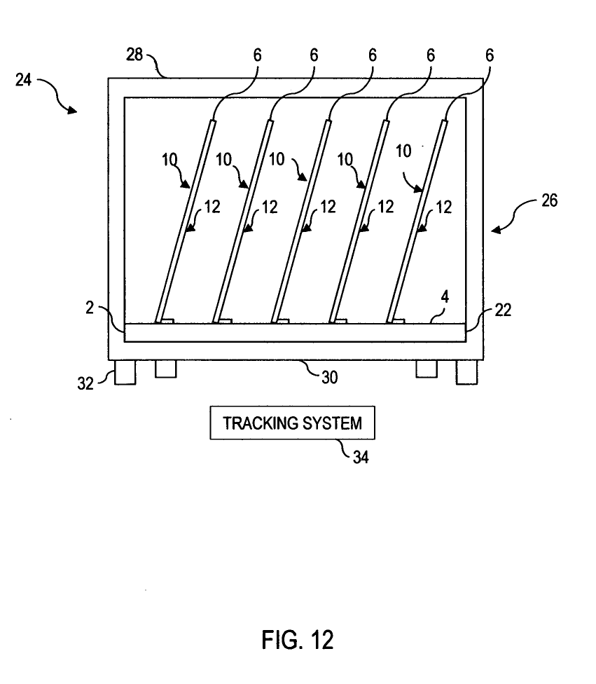

Referring now to FIG. 12, a cross section of a system 24 is depicted. The system 24 comprises a solar panel 2, a foundational base 30, and a tracking system 34. In the illustrated embodiment, the solar panel 2 comprises a cell mounting surface 4, a reflective surface, and a bottom 22. The cell mounting surface 4 further comprising a set of cell arrays 6, wherein each cell array 6 comprises a photon absorbent surface 10 and a reflective surface 12 opposite the photon absorbent surface 10. In the illustrated embodiment, the bottom 22 of the solar panel 2 is fixedly coupled to the foundational base 30. In alternative embodiments, the solar panel 2 is not fixedly coupled to the foundational based 30 but rather merely lies within the foundational base 30.

In the illustrated embodiment, the foundational base 30 comprises side walls 26 and a support frame 32. An interior of the side walls 26 comprises a reflective surface in order to maximize the opportunity to recapture reflected sunlight. The interior of the side walls 26 further comprises thermal properties in order to control the heat produced by the system 24. An excess amount of heat within a solar panel can reduce its output efficiency up to twenty-five percent. As the temperature of a solar panel increases, its output current increases exponentially while a voltage output is reduced linearly. In an alternative embodiment, the interior of the side walls 26 is a non-reflective surface. Rather, the interior of the side walls 26 only comprises thermal control capabilities.

In the illustrated embodiment, the side walls 26 of the foundational base 30 form a box-like structure. The foundational base 22 is a schematic representation of a shadow box. The side walls 26 are tall enough and cooperate with a cover 28 to enclose the solar panel system 24. This provides a significant advantage of protecting the solar panel system 24 from environmental factors such as, wind, rain, snow, or any combination thereof. In the illustrated embodiment, the cover 28 is a transparent weather cover to allow sunlight to penetrate the cover 28 and impinge the photon absorbent surfaces 10 of the cell arrays 6. By way of example, a transparent weather cover 28 allows the solar panel system 24 to be protected from environmental factors while continuing to absorb sunlight. In an alternative embodiment, the cover 28 is a solid, transparent cover.

Enclosing the solar panel 2 provides the further advantage of eliminating heat. Photovoltaic cell efficiency is directly correlated with temperature. For example, as the temperature of the solar panel 2 increases, an output current increases exponentially while a voltage output is reduced linearly. In this solar panel 2, the shadow box reduces the amount of heat retained by the solar panel 2. In a first example, implementation, the system 24 has roughly twenty percent higher efficiency when enclosed in the shadow box because the shadow box comprises thermal control capabilities.

The support frame 32 further couples the foundational based 30 to a tracking system 34. Conventional solar panels increase efficiency by tracking the sun not only along a single axis, but on two perpendicular axes. The tracking system 34 is a device which updates the alignment of the solar panel 2 such that the photon absorbent surface 10 of the set of cell arrays 6 is held at a relative angle facing the sun. In the illustrated embodiment, the tracking system 34 has one axis of operation. One axis of operation tracks the suns daily north and south position. Utilizing one axis of operation uses less energy than a dual axis operation and thereby uses less of the voltage output of the system 24 than a dual axis operation.

In an alternative embodiment, the tracking system 34 operates on dual axis operation. A dual axis of operation requires both a fixed position from north to south and a fixed position from east to west while tracking the sun throughout the day. A dual axis of operation allows for optimum solar energy levels due to its ability to follow the sun both vertically and horizontally. In the illustrated embodiment, the tracking system 34 is a computer driven tracking system which operates on one or two axis of operation. In an alternative embodiment, the tracking system is a sensor driven tracking system which operates on single or dual axis of operation. In even further alternative embodiments, the tracking system operates on both computer and sensor tracking systems which operates on one axis of operation, dual axis of operation, or a combination thereof.

In conventional solar panel systems, the solar panel is generally in a fixed operation. Meaning, the solar panel is stationary with the cell arrays co-planar with the cell support surface. If a tracking system is used with a conventional solar panel, it is only used periodically throughout the day to align the solar panel with the sun. Furthermore, conventional tracking systems are generally only used in climates with optimal weather, making them a more viable solution in warm climates. In the illustrated embodiment, the tracking system 34 is coupled to the foundational base 22 and periodically aligns the system 24 with the sun. This provides the advantage of keeping the system in direct contact with the sun throughout the day and increases the systems 24 efficiency due to the cell arrays 6 being held at a relative angular position. It further protects the system 24 as the solar panel 2 is enclosed in within the shadow box 30. In an alternative embodiment, the tracking system 34 is enclosed within the shadow box 30 with further protects the tracking system 34 from environmental conditions. An enclosed tracking system makes the solar panel 2 much more viable for use harsher environmental conditions.

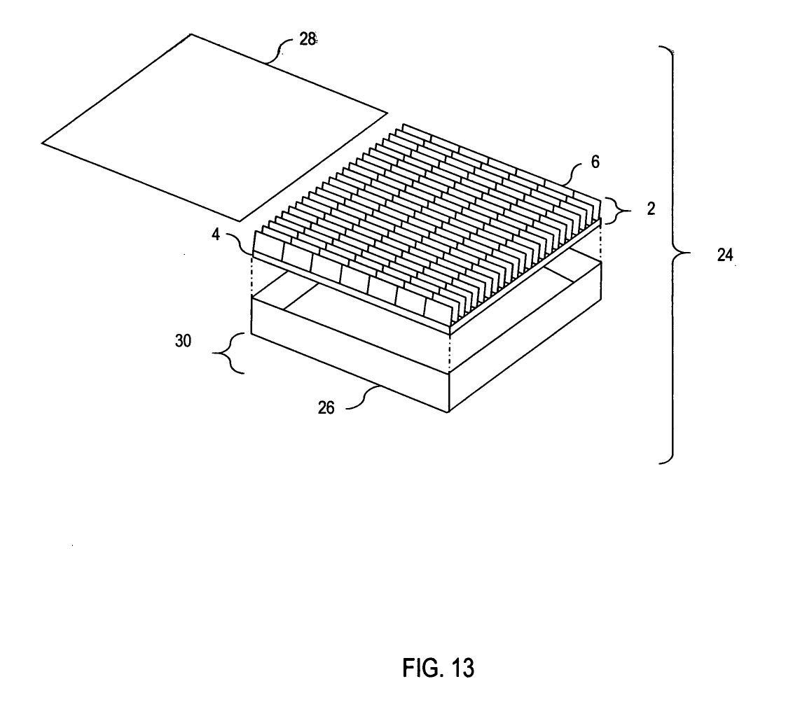

Referring now to FIG. 13, a system 24 is schematically depicted. The solar panel 2 comprises a plurality of cell arrays 6, electrically coupled and adjoined side by side on the cell mounting surface 4 of the solar panel 2. The cell arrays 6 are arranged in rows equal to a length direction of the cell mounting surface 4 such that the photon absorbent surface of each associated cell array 6 is at a relative angular position different than the cell mounting surface 4. The entire system 24 is coupled to the bottom of the foundational base 30. The side walls 26 of the foundational base 30 cooperates with a transparent weather cover 28 to enclose the system 24. Advantages of this system 24 was discussed in previous paragraphs.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the invention in the form disclosed. Many modifications and variations will be apparent to those of ordinary skill in the art without departing from the scope and spirit of the invention. Aspects of the disclosure were chosen and described in order to best explain the principles of the invention and the practical application, and to enable others of ordinary skill in the art to understand the invention for various embodiments with various modifications as are suited to the particular use contemplated.

1. A solar panel, comprising:
a cell mounting surface; and
a cell array having a photon absorbent surface, the cell array coupled to the cell mounting surface such that the photon absorbent surface of the cell array is at an angular position different than the cell mounting surface.

2. The solar panel of claim 1, wherein:
the cell mounting surface comprises a reflective surface.

3. The solar panel of claim 1, wherein:
the cell mounting surface comprises a rigid structure.

4. The solar panel of claim 1 further comprising:
a support that rigidly and fixedly orients the entire photon absorbent surface of the cell array at the angular position different than the cell mounting surface.

5. The solar panel of claim 1 further comprising:
a frame that couples the cell array to the cell mounting surface.

6. The solar panel of claim 5, wherein:
the frame is rectangular and comprises an attachment that couples the frame to the cell mounting surface such that the photon absorbent surface of the cell array is supported at an angular position different than the cell mounting surface.

7. The solar panel of claim 1, wherein:
the cell array defines a first cell array;
further comprising:
a second cell array having a photon absorbent surface at an angular position different than the cell mounting surface;
wherein:
a footprint is defined as a surface area on the cell mounting surface that the first cell array would take up if the photon absorbent surface of the first cell array were coplanar with the cell mounting surface; and
the first cell array and the second cell array both positioned within the footprint.

8. The solar panel of claim 7, wherein:
the first cell array and the second cell array are electrically coupled, adjoined side by side along a length direction of the cell mounting surface.

9. The solar panel of claim 7, wherein:
a combined efficiency of the first cell array and the second cell array is greater than an efficiency of a select one of the first cell array or the second cell array positioned coplanar to the cell mounting surface positioned within the footprint.

10. The solar panel of claim 1, wherein:
the angular position of the photon absorbent surface of the cell array is greater than 0 degrees and less than 80 degrees relative to the cell mounting surface.

11. The solar panel of claim 1, wherein:
the angular position of the photon absorbent surface of the cell array is greater than 70 degrees and less than 90 degrees relative to the cell mounting surface.

12. The solar panel of claim 1, wherein:
the cell array further comprises a reflective surface opposite the photon absorbent surface.

13. A solar panel, comprising:
a cell mounting surface;
a first cell array with a photon absorbent surface and a reflective surface opposite the photon absorbent surface, the first cell array coupled to the cell mounting surface such that the photon absorbent surface of the first cell array is at an angular position different than the cell mounting surface; and
a second cell array with a photon absorbent surface, the second cell array coupled to the cell mounting surface such that the photon absorbent surface of the second cell array is at an angular position different than the cell mounting surface.

14. The solar panel of claim 13, wherein:
the photon absorbent surface of the first cell array and the photon absorbent surface of the second cell array are each arranged greater than 5 degrees and less than 20 degrees from normal of the cell mounting surface.

15. The solar panel of claim 13, wherein:
the cell mounting surface comprises a reflective surface.

16. The solar panel of claim 15, wherein:
the reflective surface reflects light that impinges thereon to the photon absorbent surface of the first cell array, the photon absorbent surface of the second cell array, the reflective surface of the first cell array, and the photon absorbent surface of the second cell array, or a combination thereof.

17. The solar panel of claim 13, wherein:
the reflective surface of the first cell array is facing and in front of the photon absorbent surface of the second cell array such that at least a portion of the light impinging upon the reflective surface of the first cell array is reflected to the photon absorbent surface of the second cell array.

18. A system, comprising:
a panel having a reflective cell mounting surface;
a first cell array with a photon absorbent surface and a reflective surface opposite the photon absorbent surface, the first cell array coupled to the reflective cell mounting surface such that the first cell array is at an angular position different than the reflective cell mounting surface;
a second cell array with a photon absorbent surface, the second cell array coupled to the reflective cell mounting surface such that the second cell array is at an angular position different than the reflective cell mounting surface;
a foundational base coupled to the bottom of the panel; and
a tracking system that controls an angle of the panel relative to the foundational base that re-orients the position of the photon absorbent surface of the first cell array and the photon absorbent surface of the second cell array relative to a position of the sun.

19. The system of claim 18, wherein:
the tracking system comprises a controller coupled to a sensor assembly to control the angle of the panel along at least one axis.

20. The system of claim 18, wherein the foundational base comprises:
side walls;
a support frame extending above the side walls;
a bottom; and
a transparent weather cover;
wherein:
the panel is affixed to the bottom of the foundational base;
the side walls cooperate with the transparent weather cover to enclose the system; and
the support frame is coupled to the tracking system.
